(19) United States
(12) Patent Application Publication
(10) Pub. No.: US 2012/0001211 A1
(43) Pub. Date: Jan. 5, 2012

(54) Double layer injection mould LED bulb

(76) Inventor: Han-Ming Lee, Hsinchu City (TW)

(21) Appl. No.: 12/803,496

(22) Filed: Jun. 30, 2010

(51) Int. Cl. H01L 33/52; H01L 33/58; B29C 45/14

(52) U.S. Cl. 257/98; 264/272.15; 257/E33.059; 257/E33.067

(57) ABSTRACT

The present invention relates to a double layer injection mould LED bulb, in which the main improvements are: the epoxy resin light body at the top of the conducting bracket of a traditional LED light is specially designed as one epoxy resin injection mould body integrated with a PC or injection mould shell; two positioning grooves are provided on the right and left of the opening at the lower part of the shell so that the two shoulders of the conducting bracket may slide into the grooves for positioning and a small quantity of injection mould body may be condensed and moulded shortly after injection. The upper end of the internal opening of the shell is a semi-round flat convex space to give the injection the light source amplifying convex lens block function, which, together with the convex or concave structure design at the top of the shell, provides the special function of amplifying or concentrating the light source already amplified inside, so as to significantly simplify the manufacture process and increase the output capacity of mass production.

### BACKGROUND OF THE INVENTION

As shown in FIG. 1, a conventional power-saving LED light is manufactured by inserting chips and gold threads into the chip cup at the top of the conducting bracket and then transferring them to the mold for injection of epoxy resin for integration, and the light emitted by the chips at the top is diffused via the epoxy resin. Since the entire light body is of a epoxy resin structure, the injection condensing process is therefore time consuming and inconvenient, which increases the cost of the manufacturer and reduces its competitiveness, making it indeed necessary to improve the structure of the LED light.

### SUMMARY OF THE INVENTION

The primary purpose of the present invention is to provide a double layer injection mould LED bulb, in particular to one in which the epoxy resin light body at the top of the conducting bracket is a PC or injection resin shell combined with the epoxy resin injection mould, so as to simplify the manufacture process and increase the output capacity of mass production significantly.

The second purpose of the present invention is to provide a double layer injection mould LED bulb, wherein two positioning grooves are provided on the right and left of the opening at the lower part of the shell so that the two shoulders of the conducting bracket may slide into the grooves for positioning and a small quantity of injection mould body may be condensed and moulded shortly after injection.

A third purpose of the present invention is to provide a double layer injection mould LED bulb, wherein the shell may be standardized for mass production, the upper end of the inner opening is a semi-round flat convex space so that the injection attains the light source amplifying function.

A fourth purpose of the present invention is to provide a double layer injection mould LED bulb, wherein the upper end of the shell may be of the convex or concave structure design to provide the special function of amplifying or concentrating the light source already amplified inside through the shell.

### BRIEF DESCRIPTION OF THE DRAWINGS

FIG. 1 shows the schematic of the traditional structure.

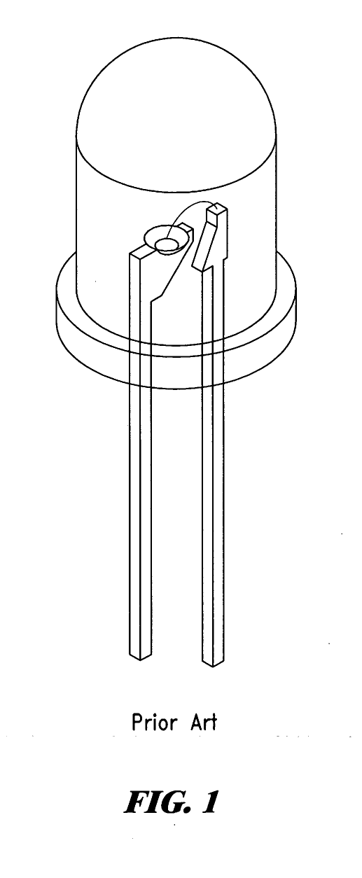

FIG. 2 shows the 3D diagram of the present invention.

FIG. 3 shows the schematic diagram of the components of the present invention.

FIG. 4 shows the schematic of the cross-section of the present invention.

FIG. 5 shows the schematic of the convex function of the shell of the present invention.

FIG. 6 shows the schematic of the convex function of the shell of the present invention.

### DETAILED DESCRIPTION OF THE PREFERRED EMBODIMENT

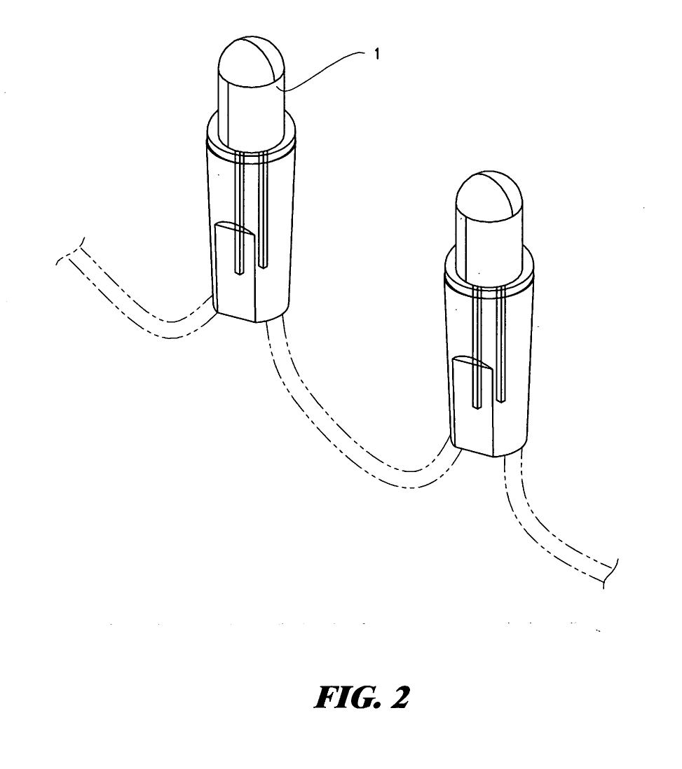

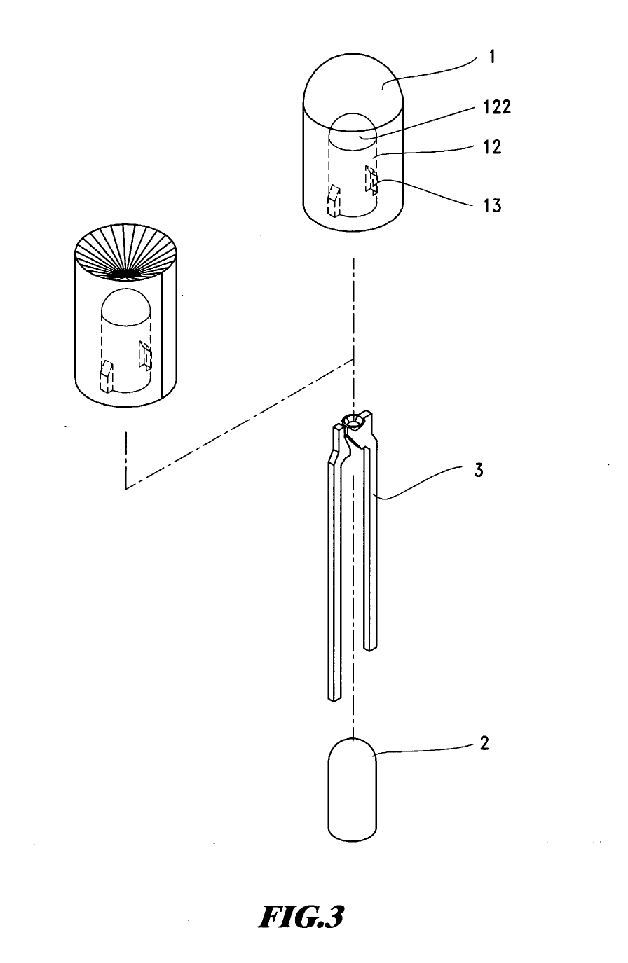

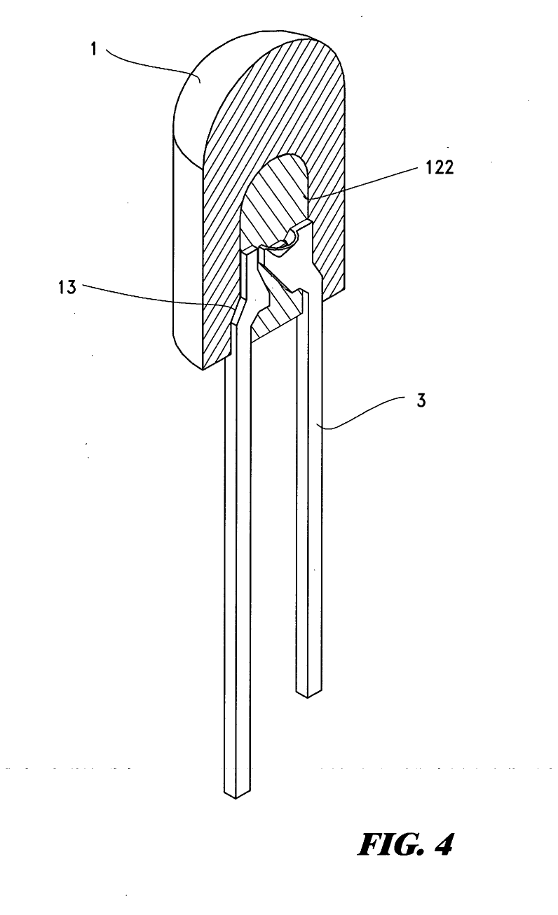

Please refer to FIGS. 2 through FIGS. 4, the present invention relates to a double layer injection mould LED bulb, wherein the main improvements are: the shell (1) is a PC or injection mould resin shell, and the center of the shell is provided with a cylindrical downward opening (12) structure, the upper end of the opening is a semi-round flat convex space (122), two positioning grooves are provided on the right and left at the lower part of the opening so that (13) the two shoulders of the traditional conducting bracket (3) slide into the grooves (13) for positioning; the injection body (2) is a small quantity of epoxy resin that may be filled into the opening (12) of the above-mentioned shell (1) for condensing and moulding within a short period of time.

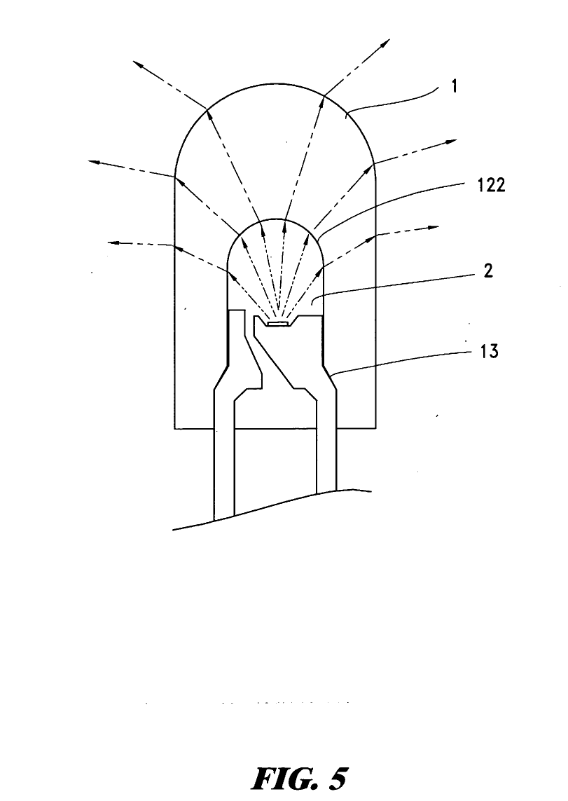

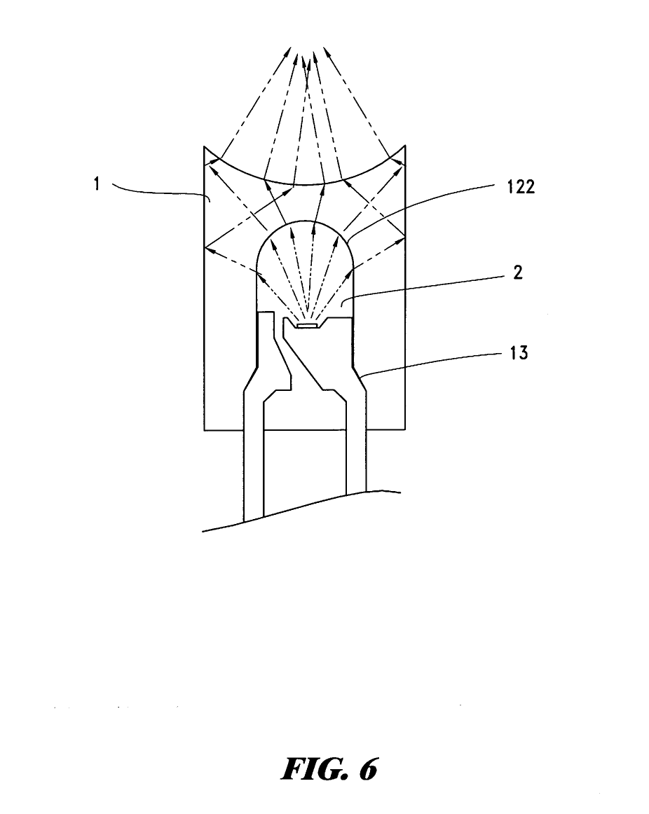

Please refer to FIG. 5 through FIG. 6 for one embodiment of the present invention. The epoxy resin light body at the top of the traditional LED light is specially designed into one shell (1) integrated with one injection body (2) so that the shell may be standardized for mass production. After the two shoulders of the conducting bracket slide into the grooves (13) for positioning, a small quantity of injection body (3) is injected within a short period of time for rapid condensing and moulding so as to simplify the manufacture process and increase the output capacity of mass production.

The upper end of the internal opening of the shell is a semi-round flat convex space (122) for the injection body (3) to attain the light source amplifying convex lens block (31) function after injection, which, together with the shell (1) whose upper end is of the convex or concave structure, provides the light source of the internal LED chip amplified by the convex lens (31) and the special light source may be amplified or concentrated through the convex or concave of the shell so as to improve the special effects of the existing single lighting deflection technology.

I claim:

1. A double layer injection mould LED bulb, wherein the main improvements are: a LED bulb, the center of which is provided with a downward opening, and in which the upper end of the opening is a semi-round flat convex space and two positioning grooves are provided on the right and left of the lower part of the opening so that the two shoulders of the conducting bracket slide into the grooves for positioning; the injection is a small quantity of epoxy resin to be filled into the opening of the shell, to be condensed and moulded with the conducting bracket within a short period of time, so as to simplify the manufacture process and increase the output capacity of mass production.

2. The double layer injection mould LED bulb wherein the upper end of the shell is of the convex or concave structure according to claim 1 provides the function that the internal light source may be amplified or concentrated again.
